(19) United States
(12) Patent Application Publication
(10) Pub. No.: US 2007/0069259 A1
(43) Pub. Date: Mar. 29, 2007

(54) CMOS image sensor and method of manufacturing the same

(75) Inventor: In Gyun Jeon, Gunpo-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/527,396

(22) Filed: Sep. 27, 2006

(30) Foreign Application Priority Data
Sep. 28, 2005 (KR) 10-2005-0090455

(51) Int. Cl. H01L 31/113

(52) U.S. Cl. 257/291

(57) ABSTRACT

A CMOS image sensor, and method for manufacturing the same is provided. The CMOS image sensor includes a device isolation film formed in a device isolation region of a semiconductor substrate to define an active region and a device isolation region, a gate insulation film formed on the semiconductor substrate. The gate insulation film has different thicknesses at the interface with the device isolation film and an interface with the active region. A gate electrode is formed on the gate insulation film. A floating diffusion region is formed in the semiconductor substrate at one side of the gate electrode. A photodiode region is formed in the semiconductor substrate at the other side of the gate electrode.

This application is based upon and claims the benefit of priority to Korean Application No. 10-2005-0090455, filed on Sep. 28, 2005, the entire contents of which are incorporated herein by reference.

### BACKGROUND

1. Technical Field

The present invention relates to a CMOS image sensor, and more particularly, to a CMOS image sensor having improved characteristics and a method of manufacturing the same.

2. Background of the Related Art

In general, an image sensor is a semiconductor IC device that converts optical images into electrical signals. Image sensors are typically classified into two types: a charge-coupled device (CCD) and a CMOS image sensor.

A CCD image sensor typically includes a plurality of vertical charge-coupled devices (VCCD) in which a plurality of photodiodes (PDs) for converting a photo-signal into an electrical signal are arranged in a matrix form, horizontal charge-coupled devices (HCCD), and sense amplifiers. The VCCD is generally formed between the photodiodes, which are vertically arranged in a matrix form, and transmits electrical charges generated from each photodiode in a vertical direction. The HCCD transmits the electrical charges, transmitted by the VCCD, in a horizontal direction. The sense amplifier detects the electrical charges transmitted in the horizontal direction and produces electrical signals according to the detected electrical charges.

CCD image sensors, however, can be difficult to drive, consume a large amount of power, and often require complicated multi-step photolithography steps in manufacturing. In addition, it can be difficult to integrate control circuits, signal processors, A/D converters, etc. on a CCD chip, making it difficult to reduce the size of the CCD chip, and subsequently the CCD image sensor.

Recently, in order to overcome the above drawbacks to CCD image sensor, CMOS image sensors are being looked at as a possible replacement for CCD sensors. A CMOS image sensor employs CMOS technology, which uses control circuits, signal processing circuits as peripheral circuits, to form MOS transistors corresponding to the number of unit pixels in a semiconductor substrate. Thus, output from each unit pixel is sequentially sensed by the MOS transistors, and a switching mode is adopted. In a CMOS image sensor, a photodiode and a MOS transistor are formed in the unit pixel. The CMOS image sensor is adapted to acquire an image by sequentially detecting electrical signals of the respective unit pixels according to the switching method.

Since the CMOS image sensor is manufactured through a CMOS manufacturing technology, it has advantages such as relatively low power consumption and simplified manufacturing process through relatively lower numbers of photolithographic steps.

Furthermore, a CMOS image sensor has an architecture where control circuits, analog-to-digital converters, and the like are integrated into the image sensor chip, thereby allowing for an image sensor that can be reduced in size.

Given these advantages over typical CCD image sensors, CMOS image sensors have been widely employed in a variety of applications such as digital still cameras, digital audio cameras, and the like.

The typical CMOS image sensor is classified into 3T, 4T, 5T types and so on according to the number of transistors. For example, 3T type comprises one photodiode and three transistors in each unit pixel and 4T type comprises one photodiode and four transistors in each unit pixel.

Hereafter, a lay-out for a unit pixel in a typical 4T CMOS sensor will be described. FIG. 1 is an equivalent circuit for a unit pixel in a common 4T CMOS image sensor. FIG. 2 is a layout showing a unit pixel in the common 4T CMOS image sensor.

As shown in FIG. 1, a unit pixel 100 of a CMOS image sensor includes a photodiode 10 as a photoelectric converter and four transistors. The four transistors include a transfer transistor 20, a reset transistor 30, a drive transistor 40 and a select transistor 50. In addition, a load transistor 60 is electrically connected to the output terminal (OUT) of unit pixel 100.

References FD, TX, Rx, Dx and Sx respectively denote a floating diffusion region, a gate voltage of the transfer transistor 20, a gate voltage of the reset transistor 30, a gate voltage of the drive transistor 40, and a gate voltage of the select transistor 50.

As shown in FIG. 2, in a unit pixel of a common 4T CMOS image sensor, an active region 73 is defined and a device isolation film 63 is formed surrounding active region 73. A single photodiode PD is formed in a wider area of the active region, and gate electrodes 23, 33, 43, and 53 of four transistors are formed to overlap the remaining area of the active region.

Transfer transistor 20 comprises gate electrode 23, reset transistor 30 comprises gate electrode 33, drive transistor 40 comprises gate electrode 43, and select transistor comprises gate electrode 53.

Impurity ions are then injected into active regions 73 of the respective transistors, into areas adjacent to respective gate electrodes 23, 33, 43, and 53, to thereby form a source/drain region (S/D) of each transistor.

FIG. 3 is a section view taken along the line I-I′ in FIG. 2 showing a conventional CMOS image sensor.

As shown in FIG. 3, a low concentration P⁻ type epitaxial layer 62 is formed in a high concentration P⁺⁺ type semiconductor substrate 61. A device isolation film 63 is formed in a device isolation region of the semiconductor substrate 61 where P-epitaxial layer 62 is formed.

Thereafter, a gate insulation film 64 is formed on the whole surface of semiconductor substrate 61 and a gate electrode 65 of, for example, a transfer transistor Tx, is formed on gate insulation film 64.

Here, P-epitaxial layer 62 between device isolation films 63 under the gate electrode 65 establishes a channel region C.

The above-configured transfer transistor Tx functions to transfer electrons smoothly from the photodiode (PD in FIG. 2) to the floating diffusion region (FD in FIGS. 1 and 2). That is, electrons are transferred from photodiode PD to floating diffusion FD region through channel region C, which is formed under gate electrode 65 of transfer transistor Tx.

However, the above conventional CMOS image sensor has associated drawbacks. For example, a small quantity of electrons flowing near the interface between channel region C and device isolation film 63 are lost due to interface defects of device isolation film 63 (i.e., lost as leakage current in the interface of the device isolation film), thereby degrading characteristics of the image sensor.

### SUMMARY

The present invention has been made in order to solve the above problems, and to provide a CMOS image sensor and a method of manufacturing the same, which prevents a leakage current from occurring in the interface of the device isolation film to improve characteristics of the image sensor.

According to an embodiment consistent with the present invention, there is provided a CMOS image sensor comprising: a device isolation film formed in a semiconductor substrate defining an active region and a device isolation region; a gate insulation film formed on the semiconductor substrate, the gate insulation film having different thicknesses at an interface with the device isolation film and an interface with the active region; a gate electrode formed on the gate insulation film; a floating diffusion region formed in the semiconductor substrate at one side of the gate electrode; and a photodiode region formed in the semiconductor substrate at the other side of the gate electrode.

According to another embodiment consistent with the present invention, there is provided a method of manufacturing a CMOS image sensor, comprising: forming a device isolation film in a semiconductor substrate for defining the device isolation region and an active region; forming a gate insulation film on the semiconductor substrate, the gate insulation film having different thicknesses at an interface with the device isolation film and at an interface with the active region; forming a gate electrode on the gate insulation film; forming a floating diffusion region in the semiconductor substrate at one side of the gate electrode; and forming a photodiode region in the semiconductor substrate at the other side of the gate electrode.

### BRIEF DESCRIPTION OF THE DRAWINGS

FIG. 1 shows an equivalent circuit for a unit pixel in a conventional 4T CMOS image sensor.

FIG. 2 illustrates a layout showing a unit pixel in a conventional 4T CMOS image sensor.

FIG. 3 is a sectional view of the conventional CMOS image sensor taken along the line I-I′ in FIG. 2.

FIG. 4A is a sectional view of the CMOS image sensor taken along the line I-I′ in FIG. 7 consistent with the present invention.

FIG. 4B is a sectional view of the CMOS image sensor taken along the line IV-IV′ in FIG. 7 consistent with the present invention.

FIGS. 5A to 5D shows a method of manufacturing a CMOS image sensor consistent with the present invention according to sectional views taken along the line I-I′ in FIG. 7.

FIGS. 6A to 6C shows a method of manufacturing a CMOS image sensor consistent with the present invention, according to sectional views taken along the line IV-IV′ line in FIG. 7 after the gate electrode, as shown in FIGS. 5a to 5d is formed.

FIG. 7 illustrates a layout showing a unit pixel in a 4T CMOS image sensor consistent with the present invention.

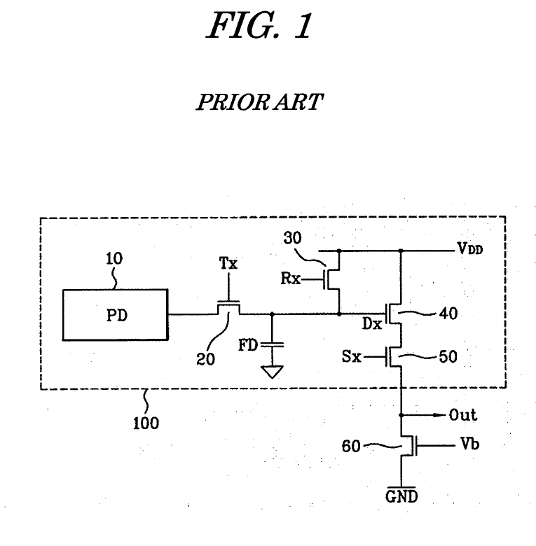

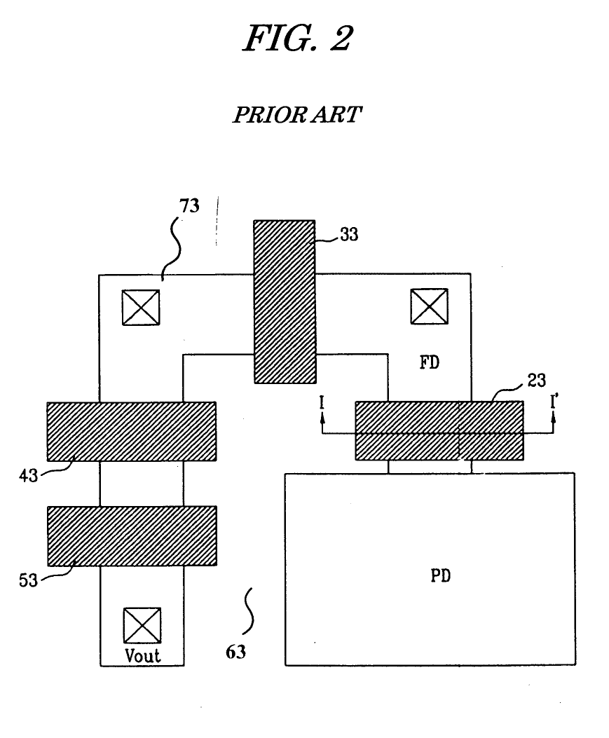

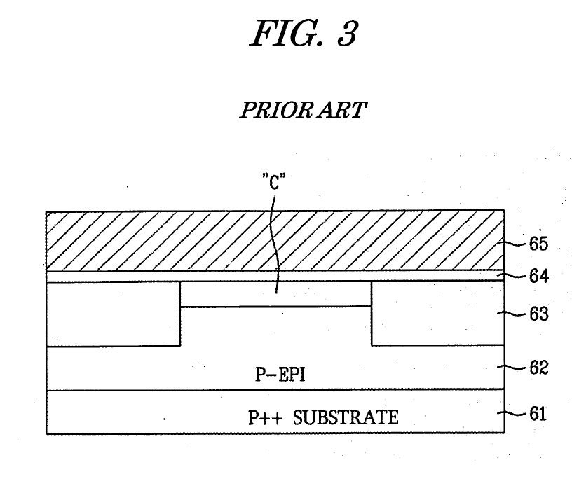

### DETAILED DESCRIPTION

Hereinafter, a CMOS image sensor and a method of manufacturing the sensor consistent with embodiments of the invention will be described in detail with reference to the accompanying drawings.

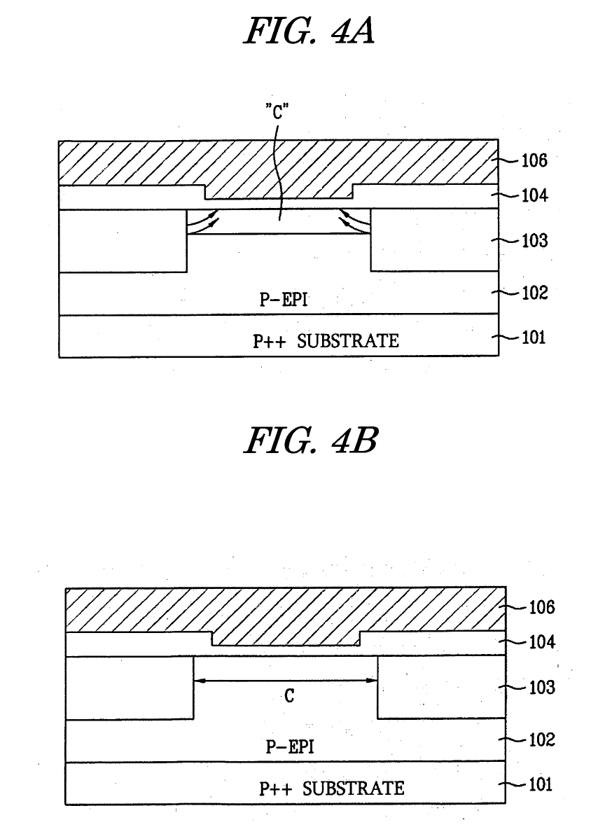

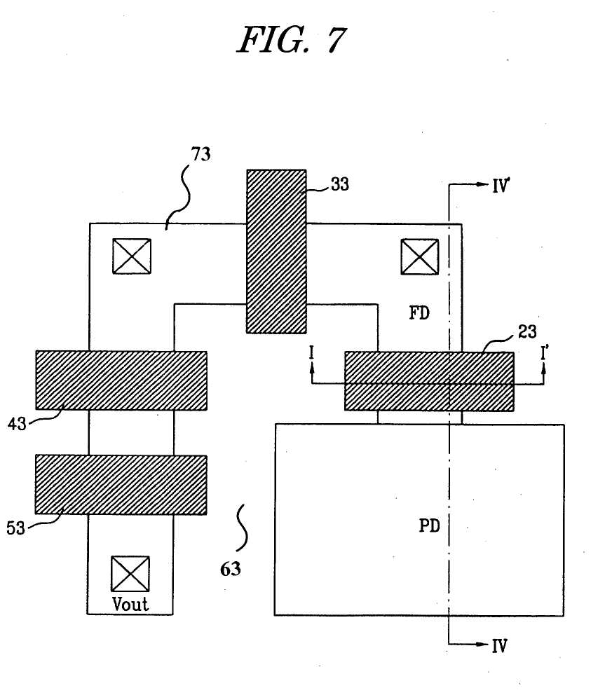

FIG. 7 illustrates a layout showing a unit pixel in a 4T CMOS image sensor consistent with the present invention. FIGS. 4A, 4B, 5A-5D, and 6A-6C, described below, are section views of the unit pixel taken along different lines to further describe in detail embodiments consistent with the present invention. As shown in FIG. 7, in a unit pixel of a common 4T CMOS image sensor, an active region 73 is defined and a device isolation film 63 is formed surrounding active region 73. A single photodiode PD is formed in a wider area of the active region, and gate electrodes 23, 33, 43, and 53 of four transistors are formed to overlap the remaining area of the active region.

A transistor 20, which in an embodiment consistent with the present invention may comprise transfer transistor Tx, comprises gate electrode 23, reset transistor 30 comprises gate electrode 33, drive transistor 40 comprises gate electrode 43, and select transistor comprises gate electrode 53.

Impurity ions are then injected into active regions 73 of the respective transistors, into areas adjacent to respective gate electrodes 23, 33, 43, and 53, to thereby form a source/drain region (S/D) of each transistor.

FIG. 4A is a sectional view taken along the line I-I′ in FIG. 7 of a CMOS image sensor consistent with an embodiment of the present invention. Similarly, FIG. 4B is a sectional view taken along the line IV-IV′ in FIG. 7 of a CMOS image sensor consistent with an embodiment of the present invention.

As shown in FIGS. 4A and 4B, a low concentration P− type epitaxial layer 102 is formed in the surface of a high concentration P++ type semiconductor substrate 101, and a device isolation film 103 is formed in a device isolation region of semiconductor substrate 101 where P-epitaxial layer 102 is formed.

A gate insulation film 104 having a variable thickness is formed on the whole surface of semiconductor substrate 103. A gate electrode 106 for a transistor, which may be for example, a transfer transistor Tx, is formed on gate insulation film 104.

A channel region C is defined as a region of P− type epitaxial layer 102 between device isolation films 103 and under gate electrode 106.

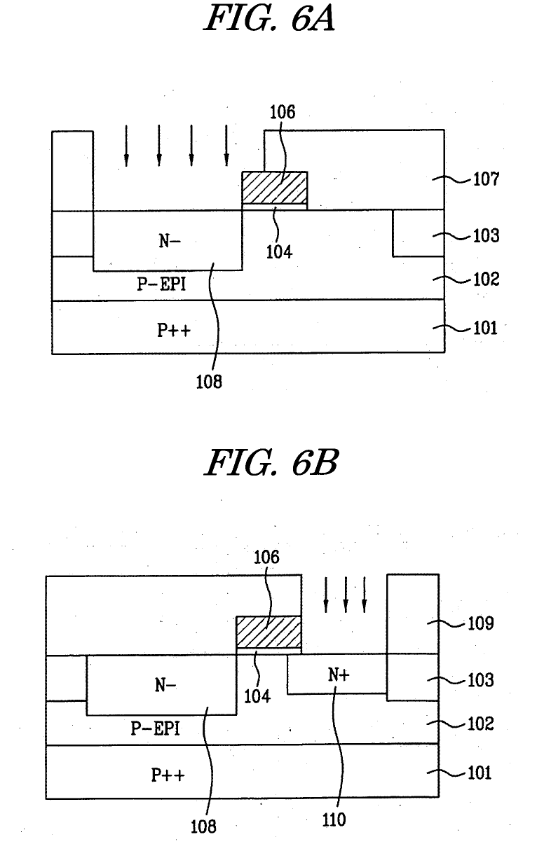

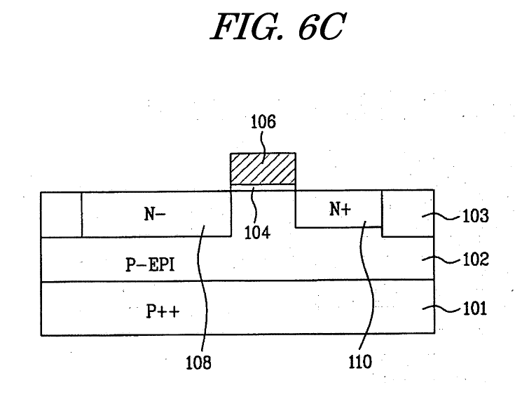

In addition, although not shown in the view illustrated in FIGS. 4a and 4b, but illustrated in, for example, FIGS. 6a-6c, an n− type diffusion region 108 is formed in the active region at one side of gate electrode 106, and an n+ type diffusion region 110 is formed in the active region at the other side of gate electrode 106. N− type diffusion region 108 acts as a photodiode region and n+ type diffusion region 110 acts as a floating diffusion region.

The CMOS image sensor consistent with an embodiment of the present invention is configured such that gate insulation film 103 has portions which have different thickness. That is, the portion of gate insulation film 103 formed over device isolation film 103 has a thickness which is greater than gate insulation film 103 formed at the central portion of channel region C.

With the above-configured CMOS image sensor consistent with an embodiment of the present invention, when a channel region C is formed and then electrons travel from the photodiode region to the floating diffusion region via channel region C, the electrons moves preferentially towards the central area having a stronger electric field (in the direction denoted by arrows in the figures). Thus, the relative quantity of electrons moving adjacent to device isolation film 103 can be reduced, minimizing electron loss and improving this characteristic of the image sensor.

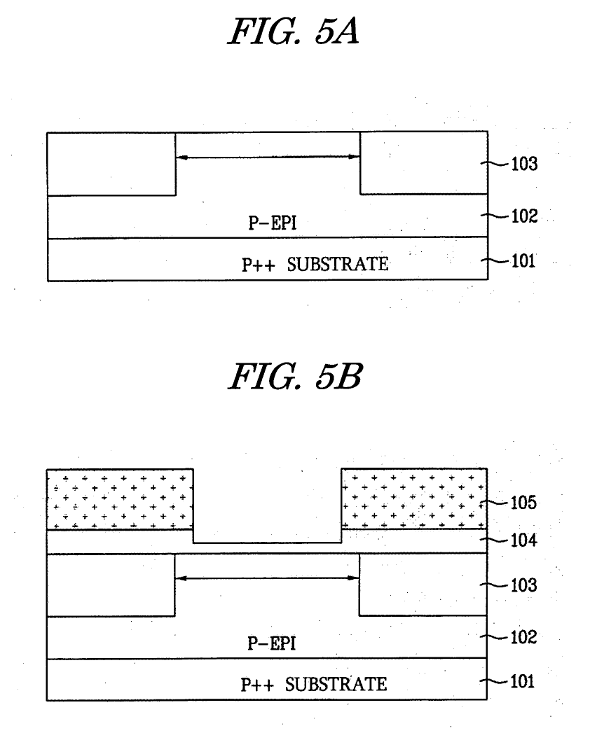

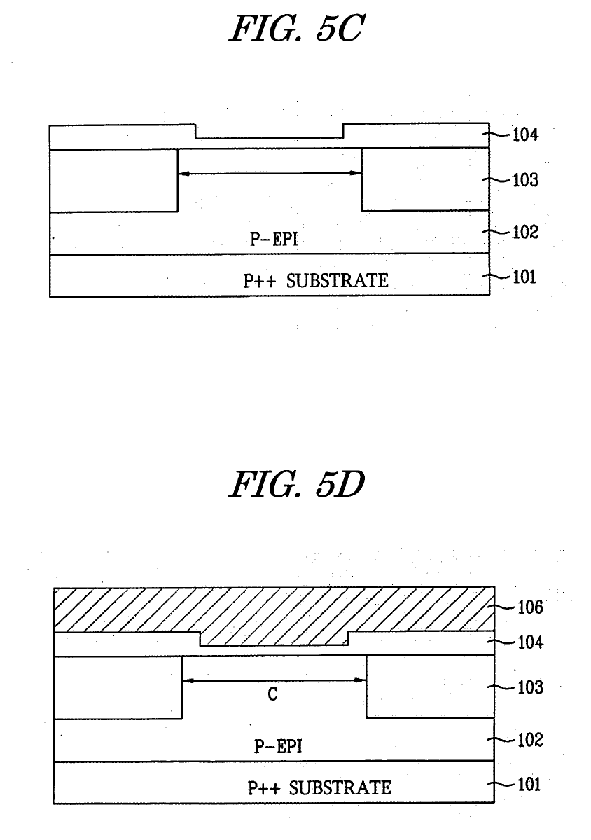

FIGS. 5A to 5D show a method of manufacturing a CMOS image sensor consistent with the present invention according to sectional views taken along the line I-I′ in FIG. 7.

As shown in FIG. 5a, using an epitaxial process, a first conductive (P− type) epitaxial layer 102 of low concentration is formed on a semiconductor substrate 101 such as a first conductive (P++ type) single crystal silicon of high concentration. Consistent with another embodiment of the present invention, semiconductor substrate may be a n−type substrate.

Here, epitaxial layer 102 is formed so as to have a large and deep depletion region for a photodiode. This enhances the photocharge collection capacity of a low voltage photodiode and furthermore improve the photosensitivity thereof.

An active region and a device isolation region are then defined in semiconductor substrate 101, and using, for example, an STI process, a device isolation film 103 is formed in the device isolation region.

Here, a method for forming device isolation film 103 will be explained although not illustrated in the figures.

First, a pad oxide film, a pad nitride film, and a TEOS (Tetra Ethyl Ortho Silicate) oxide film are sequentially formed on a semiconductor substrate and then a photosensitive film is formed on the TEOS oxide film.

Thereafter, using a mask for defining an active region and a device isolation region, the photosensitive region is exposed to light and developed to thereby pattern the photosensitive film. At this time, the photosensitive film on the device isolation region is removed.

In addition, using the patterned photosensitive film as a mask, the pad oxide film, pad nitride film, and TEOS oxide film on the device isolation region are selectively removed.

Then, using the patterned pad oxide film, pad nitride film, and TEOS oxide film as a mask, the semiconductor substrate of the device isolation region is etched to form a trench having a desired depth. The photosensitive film is then completely removed.

Thereafter, an insulation material is buried inside of the trench to form a device isolation film 103 inside of the trench. Then, the pad oxide film, pad nitride film, and TEOS oxide film are removed.

As illustrated in FIG. 5B, a gate insulation film 104 is formed to have a thickness of about 40˜70 Å on the whole surface of epitaxial layer 102.

Then, after coating a photosensitive film 105 on gate insulation film 104, a selective patterning is performed through a light-exposure and development process such that the central area between adjacent device isolation films 103 is opened.

Using patterned photosensitive film 105 as a mask, a desired thickness of gate insulation film 104 is selectively removed from the exposed surface thereof. Here, as much as about 30 Å is removed from gate insulation film 104, such that gate insulation film 104 remaining on semiconductor substrate 101 at an interface with the active region between device isolation films 103 has a thickness of about 10˜40 Å, and gate insulation film 103 formed on device isolation film 103 and semiconductor substrate 101 adjacent thereto has a thickness of about 40˜70 Å.

Consistent with another embodiment of the present invention, a first gate insulation film is formed with a thickness of about 40˜70 Å. The first gate insulation film is then selectively removed from the central portion between device isolation films 103, and a second gate insulation film having a thickness of about 10˜40 Å is formed in the area where the first gate insulation film is removed.

As illustrated in FIG. 5C, when photosensitive film 105 is removed, gate insulation film 104 has portions having different thicknesses.

As illustrated in FIG. 5D, a conductive layer (for example, a high concentration polysilicon layer) is deposited on gate insulation film 104, and then selectively removed through a photo and etching process to form the gate electrode 106 of a transistor, which may be, for example, transfer transistor Tx.

FIGS. 6A to 6C show a method of manufacturing a CMOS image sensor consistent with the present invention after the gate electrode is formed as illustrated in FIGS. 5A-5D.

As illustrated in FIG. 6A, a first photosensitive film is coated on the whole surface of semiconductor substrate 101 including gate electrode 106, and then patterned through a light-exposure and development process such that a photodiode region is opened.

As a result, patterned first photosensitive film 107 is formed so as to include part of the upper portion of gate electrode 106.

In addition, using patterned first photosensitive film 107 as a mask, n− type impurity ions of a low concentration are injected into the exposed photodiode region to form an n− type diffusion region 108, which can also be used as the source region of a transistor, which may be, for example, transfer transistor Tx.

On the other hand, if a reverse bias is applied between each of n− type diffusion regions 108 and low concentration P− type epitaxial layer 102, a depletion layer is produced. The depletion layer receives light to generate electrons, which reduce the potential of drive transistor Dx when the reset transistor Rx is turned off. The potential continues to be reduced when reset transistor Rx is turned off after being turned on, thereby generating a voltage difference. The voltage difference produces a signal that is processed to operate the image sensor.

As illustrated in FIG. 6B, after patterned first photosensitive film 107 is completely removed, a second photosensitive film is coated on the entire face of semiconductor substrate 101. Then, a patterning is carried out through a light exposure and development process such that the source/drain region of each transistor is exposed, forming patterned second photosensitive film 109.

Thereafter, using patterned second photosensitive film 109 as a mask, n+ type impurity ions of a high concentration are injected into the exposed source/drain region to form a high concentration n+ type diffusion region (floating diffusion region) 110 within semiconductor substrate 101.

Consistent with an embodiment of the present invention, the high concentration n+ type impurity ions comprise As ions and are injected with a dose quantity of about 4×1015 using an ion injection energy of about 80 keV.

As shown in FIG. 6C, patterned second photosensitive film 109 is removed. Then, a thermal treatment (for example, a rapid heat treatment process) is performed on semiconductor substrate 101 to diffuse the impurity ions within n− type diffusion region 108 and n+ type diffusion region 110. The thermal treatment is carried out such that the expanded area of n− type diffusion region 108 and n+ type diffusion region 110 becomes no more than 0.4 μm in terms of one dimension (expanded amount/side).

As described above, a CMOS image sensor consistent with the invention and its manufacturing method have the following effects of minimizing electron loss when the electrons travel from the photodiode to the floating diffusion region, because a gate insulation film has portions which have different thicknesses.

Although the present invention has been described with reference to several exemplary embodiments, the description is illustrative of the invention and is not to be construed as limiting the invention. Various modifications, variations and replacements may occur to those skilled in the art, without departing from the spirit and scope of the invention as defined by the appended claims.

What is claimed is:

1. A CMOS image sensor comprising:
a device isolation film formed in a region of a semiconductor substrate to define an active region and a device isolation region;
a gate insulation film formed on the semiconductor substrate, the gate insulation film having different thicknesses at an interface with the device isolation film and an interface with the active region;
a gate electrode formed on the gate insulation film;
a floating diffusion region formed in the semiconductor substrate at one side of the gate electrode; and
a photodiode region formed in the semiconductor substrate at the other side of the gate electrode.

2. The CMOS image sensor as claimed in claim 1, wherein the gate insulation film is formed such that the thickness thereof at the interface with the device isolation film is greater than that of the gate insulation film at the interface with the active region.

3. The CMOS image sensor as claimed in claim 2, wherein a thickness of the gate insulation film at the interface with the device isolation film is about 40˜70 Å, and a thickness of the gate insulation film at the interface with the active region is about 10˜40 Å.

4. A method of manufacturing a CMOS image sensor, comprising:
forming a device isolation film in a region of a semiconductor substrate for defining a device isolation region and an active region;
forming a gate insulation film on the semiconductor substrate, the gate insulation film having different thicknesses at an interface with the device isolation film and at an interface with the active region;
forming a gate electrode on the gate insulation film;
forming a floating diffusion region in the semiconductor substrate at one side of the gate electrode; and
forming a photodiode region in the semiconductor substrate at the other side of the gate electrode.

5. The method as claimed in claim 4, wherein forming the gate insulation film comprises:
forming a gate insulation film on a whole surface of a semiconductor substrate; and
etching the gate insulation film at the interface with the active region to a desired depth.

6. The method as claimed in claim 4, wherein forming the gate insulation film comprises:
forming a first gate insulation film on a whole surface of a semiconductor substrate;
selectively removing a portion of the first gate insulation film formed at the interface with the active region; and
forming a second gate insulation film in the removed portion of the first gate insulation film, the second gate insulation film having a thickness greater than that of the first gate insulation film.

7. The method as claimed in claim 6, wherein the first gate insulation film is formed to have a thickness of about 40˜70 Å, and the second gate insulation film is formed to have a thickness of about 10˜40 Å.
